(19) United States
(12) Patent Application Publication
(10) Pub. No.: US 2010/0071943 A1
(43) Pub. Date: Mar. 25, 2010

(54) PACKAGE AND SUBSTRATE STRUCTURE WITH AT LEAST ONE ALIGNMENT PATTERN

(75) Inventors: Tsung-Fu Tsai, Yunlin County (TW); Su-Ching Chung, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/496,646

(22) Filed: Jul. 2, 2009

(30) Foreign Application Priority Data
Sep. 24, 2008 (TW) 97136721

(51) Int. Cl. H05K 1/16; H05K 1/00

(52) U.S. Cl. 174/260; 174/250

(57) ABSTRACT

A package structure with an alignment pattern is provided, which includes a first substrate, a second substrate and at least one contact. At least one first conductive structure and at least one first alignment pattern are disposed on the first substrate. The second substrate is disposed opposite to the first substrate. In addition, at least one second conductive structure is disposed on the second substrate. The at least one contact is between the first conductive structure on the first substrate and the second conductive structure on the second structure. Particularly, the at least one first alignment pattern has at least one widest part and at least one narrowest part, and the widest part or the narrowest part is aligned or close to a central portion of the at least one contact.

### CROSS-REFERENCE TO RELATED APPLICATION

This application claims the priority benefit of Taiwan application serial no. 97136721, filed on Sep. 24, 2008. The entirety of the above-mentioned patent application is hereby incorporated by reference herein and made a part of specification.

### BACKGROUND

1. Technical Field

The disclosure relates to a package structure and a substrate with at least one alignment pattern. More particularly, analysing the bonding quality of the package structure can be assisted by fabricating alignment patterns on a substrate.

2. Background Art

With development of semiconductor fabrication technology, structure of integrated circuits (ICs) is increasingly delicate and functions thereof are increasingly complicated. Therefore, development of semiconductor package technology also has a general trend of delicacy. A conventional wire bonding technique is no longer suitable for a package process of high-density and small-size ICs. Therefore, package techniques for a chip and a carrier and for the carrier and a circuit board are required to be improved.

A flip chip (FC) bonding package technique is widely applied to devices requiring a high performance, high density and small size package. According to such package technique, corresponding contacts are formed on conductive structures of two substrates to be bonded. Then, one of the substrates is turned over for bonding all of the corresponding contacts on the two substrates, so as to complete a FC package structure. Therefore, the package structure is conceptually formed based on a ball grid array (BGA) structure.

However, contact microstructures of the FC package and the BGA device are generally analysed via a substrate polishing method, and the bonding quality thereof are analysed by observing the contact microstructures. However, the contacts of the FC package are located between two substrates, and correct positions of the contacts cannot be identified from an appearance of the product. A current method is only to identify the contact positions via the substrate polishing method before the bonding quality analysis. In detail, according to the conventional substrate polishing method, the substrate is slowly polished from the most peripheral line of contacts towards a contact position to be observed, so as to avoid excessive polishing, and then the contact microstructures are identified. However, since the method of polishing the substrate towards the contact position to be observed is not easy to be accurately controlled, and whether a central portion of the contact to be observed is approached is not easily confirmed, a difficulty of bonding quality analysis of the package structure is greatly increased.

### SUMMARY

The embodiment is directed to a package structure and a substrate with an alignment pattern and a bonding quality analysis method of the package structure for resolving a problem of a conventional method that when a substrate is polished for observing a contact, whether a central portion of a contact microstructure to be observed is approached cannot be accurately controlled.

The embodiment provides a package structure with an alignment pattern, which includes a first substrate, a second substrate and at least one contact. At least one first conductive structure and at least one first alignment pattern are disposed on the first substrate. The second substrate is disposed opposite to the first substrate, and at least one second conductive structure is disposed on the second substrate. The at least one contact is located between the first conductive structure of the first substrate and the second conductive structure of the second structure. Particular, the at least one first alignment pattern has at least one widest part and at least one narrowest part, and the widest part or the narrowest part is aligned or close to a central portion of the at least one contact.

Another embodiment provides a substrate structure with an alignment pattern, which includes a substrate and at least one contact. At least one conductive structure and at least one first alignment pattern are disposed on the substrate. The at least one contact is located on the conductive structure of the substrate. Moreover, the at least one first alignment pattern has at least one widest part and at least one narrowest part, and the widest part or the narrowest part is aligned or close to a central portion of the at least one contact.

Another embodiment provides a package structure with an alignment pattern, which includes a substrate, at least a chip and at least one contact. The substrate has at least one conductive structure. The chip is embedded in the substrate, and is electrically connected to the conductive structure in the substrate, wherein a surface of the chip has at least one alignment pattern. The at least one contact is disposed on an outer surface of the substrate. The at least one alignment pattern has at least one widest part and at least one narrowest part, and the widest part or the narrowest part is aligned or close to a central portion of the at least one contact.

Since the alignment pattern is designed on the package structure or the chip, when the substrate is polished for analysing the bonding quality of the package structure, whether the polishing process reaches the central portion of the contact can be accurately determined by observing the alignment pattern.

### BRIEF DESCRIPTION OF THE DRAWINGS

The accompanying drawings are included to provide a further understanding of the embodiment, and are incorporated in and constitute a part of this specification. The drawings illustrate embodiments and, together with the description, serve to explain the principles of the embodiment.

FIGS. 1A to 1C are cross-sectional views of a package structure with an alignment pattern according to an embodiment.

FIG. 2A and FIG. 2B are respectively front views of a first substrate and a second substrate of a package structure of FIGS. 1A to 1C. FIG. 2C shows front view of the first substrate and cross-section views along the lines a-a′, b-b′ and c-c′.

FIG. 3 is a cross-sectional view of a package structure with an alignment pattern according to another embodiment.

FIG. 4 is a cross-sectional view of a package structure with an alignment pattern according to still another embodiment.

FIG. 5 is a flowchart illustrating a method for analysing a bonding quality of a package structure according to an embodiment.

FIG. 6A and FIG. 6B are amplified diagrams of an alignment pattern and a contact according to another embodiment.

FIG. 7 is a cross-sectional view of a package structure with an alignment pattern according to another embodiment.

### DESCRIPTION OF EMBODIMENTS

In the following, a plurality of embodiments is provided to describe a package structure with an alignment pattern and a bonding quality analysis method of the package structure with reference of figures, so that those skilled in the art can understand the concept of the embodiment.

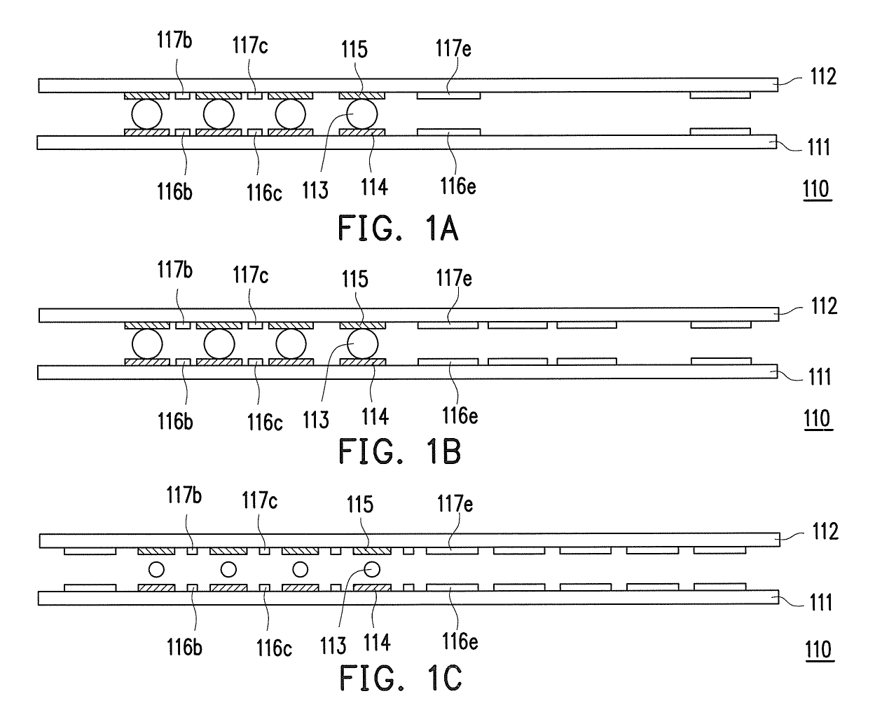

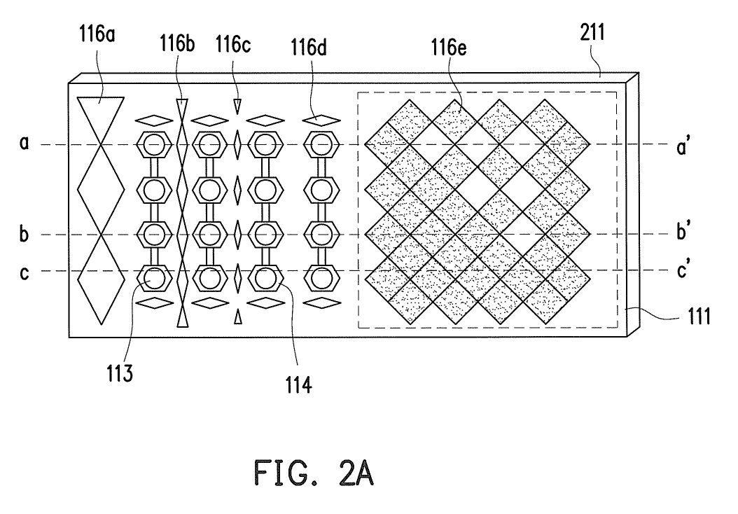

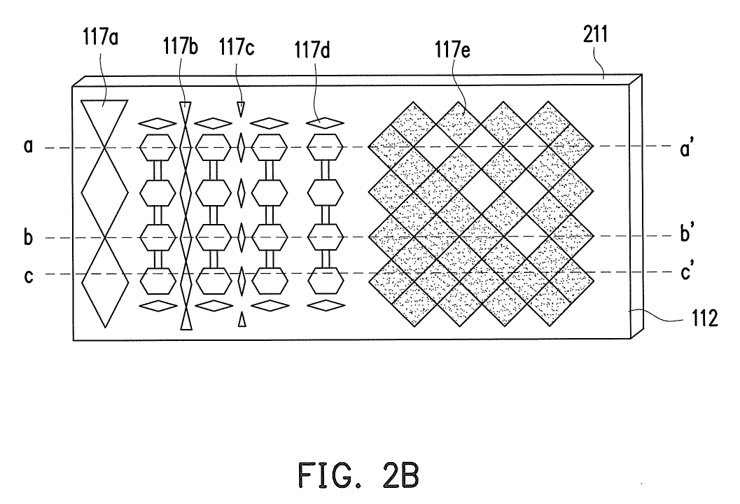

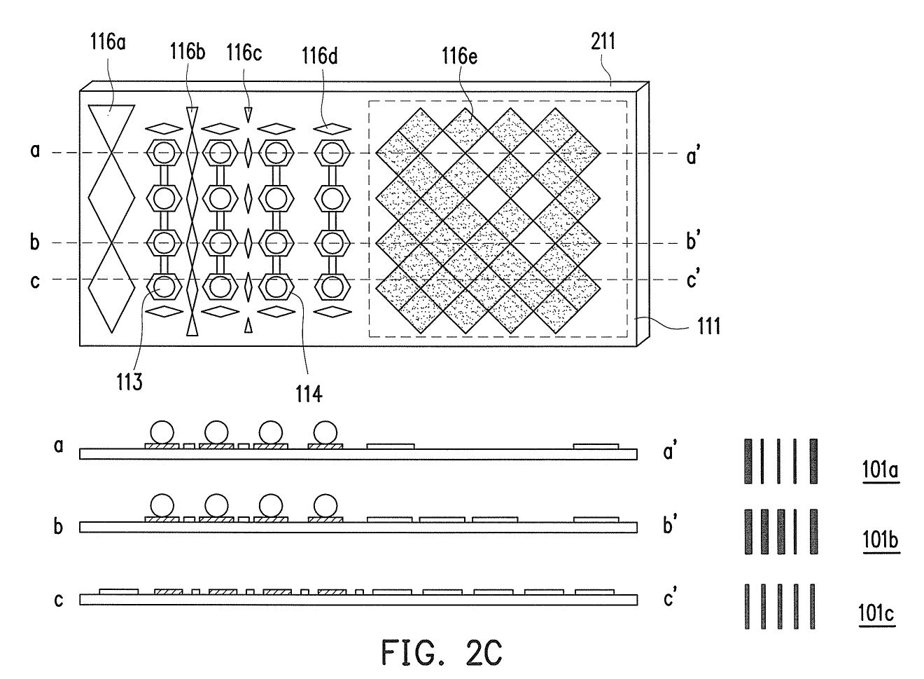

FIG. 1A is a cross-sectional view of a package structure with an alignment pattern according to an embodiment. FIG. 2A and FIG. 2B are respectively front views of a first substrate and a second substrate of the package structure of FIG. 1A, wherein a cross-sectional structure of FIG. 1A corresponds to a sectional line a-a′ of FIG. 2A and FIG. 2B. Referring to FIG. 1A, FIG. 2A and FIG. 2B, the package structure 110 with the alignment pattern includes a first substrate 111, a second substrate 112 and at least one contact 113. The second substrate 112 is disposed opposite to the first substrate 111, and the contacts 113 are disposed between the first substrate 111 and the second substrate 112. In other embodiments, the first substrate 111 and the second substrate 112 respectively can be a chip, a glass substrate, a ceramic substrate, a plastic substrate or a metal substrate.

As shown in FIG. 2A, at least one first conductive structure 114 and at least one first alignment pattern 116a-116e are disposed on a surface of the first substrate 111. The first conductive structure 114 is, for example, a pad structure which can be electrically connected to an integrated circuit or a device formed on the first substrate 111 or in the first substrate 111. In other embodiments, the first conductive structure 114 is, for example, an outermost layer of metal of an integrated circuit, an outermost layer of metal of a redistribution layer (RDL), or a surface copper wiring of a printed circuit board (PCB).

Moreover, the first alignment patterns 116a-116e are formed on the first substrate 111, which can be, for example, defined together with the first conductive structure 114. In other words, during fabrication of the outermost layer of metal of the integrated circuit, the outermost layer of metal of the RDL, or the surface copper wiring of the PCB, the alignment patterns can be simultaneously fabricated on the substrate.

In the embodiment, the widest part or the narrowest part of each of the first alignment patterns 116a-116e is aligned or close to a central portion of each of the contacts 113. The central portion of the contact can be totally aligned to the widest part or the narrowest part of the alignment pattern, or the central portion of the contact can be close to the widest part or the narrowest part of the alignment pattern, which is not totally aligned thereto, directly. In the following content, the central portion of the contact totally aligned to the widest part or the narrowest part of the alignment pattern is first taken as an example.

For example, the narrowest part of the alignment pattern 116a is aligned to the central portion of the contact 113. The widest part of the alignment pattern 116b is aligned to the central portion of the contact 113. A purpose of aligning the widest parts or the narrowest parts of the alignment patterns 116a-116e to the central portions of the contacts 113 is that when a substrate polishing is performed for analysing the contacts, as polished positions of the substrate are varied, exposed positions of the alignment patterns are also varied. Therefore, by determining the positions of the widest parts or the narrowest parts of the alignment patterns, whether the central portion of the contact is approached can be determined, so that the alignment patterns can serve as reference patterns for the substrate polishing.

Moreover, in the embodiment, as shown in FIG. 2A, the first alignment patterns 116a-116e can be located at an edge of the first substrate 111 or between the contacts 113. The alignment pattern 116d located at the edge of the first substrate 111 serves as an initial alignment mark for notifying that a contact position is approached during a follow-up polishing process. According to an embodiment, the first alignment patterns 116a-116e can be disposed as one-dimensional arrangement (such as the arrangement of the alignment patterns 116a to 116d), which are arranged along one direction (X direction). According to another embodiment, the first alignment patterns 116a-116e can also be disposed as two-dimensional arrangement (such as the arrangement of the alignment patterns 116e), which are arranged along two directions (X and Y directions). For example, as shown in FIG. 2C, the alignment patterns 116e at the line a-a′ can be read as “10001”; the alignment patterns 116e at the line b-b′ can be read as “11101”; and the alignment patterns 116e at the line c-c′ can be read as “11111”. That is, the alignment patterns 116e serves as bar codes 101a, 101b and 101c. The users can identify the positions of the contacts 113 according to reading the bar codes 101a, 101b and 101c generated from the alignment patterns 116e.

Moreover, the first alignment patterns 116a-116e can be consecutively arranged, which is shown as the arrangement of the alignment patterns 116a and 116b; or can be inconsecutively arranged, which is shown as the arrangement of the alignment patterns 116c. Moreover, sizes of the first alignment patterns 116a-116e can be different, for example, the size of the alignment pattern 116a is greater than that of the alignment pattern 116b. In addition, shapes of the first alignment patterns 116a-116e are for example, diamonds, though the present invention is not limited thereto. In other embodiments, the shapes of the first alignment patterns 116a-116e can also be other geometric patterns such as diamonds, rounds, ovals, parallelograms, squares, triangles or polygons.

Besides, as shown in FIG. 1A, the contacts 113 are located between the first conductive structure 114 of the first substrate 111 and the second conductive structure 115 of the second substrate 112. In the embodiment, the contacts 113 are formed on the first conductive structure 114 of the first substrate 111 (as shown in FIG. 2A), and after the first substrate 111 is bonded to the second substrate 112, the contacts 113 are then located between the first substrate 111 and the second substrate 112. In other embodiments, the contacts 113 can also be formed on the second substrate 112, and then the first substrate 111 and the second substrate 112 are bonded.

It should be noted that in the embodiment, the contacts 113 arranged on the first conductive structure 114 of the first substrate 111 are for example, a ball grid array (BGA) structure, which is for example a solder BGA. However, the embodiment is not limited thereto, and in other embodiments, the contacts 113 can also be metal bumps, or can be formed by polymer bumps and a metal layer covering the polymer bumps.

Referring to FIG. 1A and FIG. 2B, at least one second conductive structure 115 is disposed on the surface of the second substrate 112. Similarly, the second conductive structure 115 is for example, the pad structure, the outermost layer of metal of the integrated circuit, the outermost layer of metal of the RDL, or the surface copper wiring of the PCB.

Moreover, in the embodiment, at least one second alignment pattern 117a-117e is disposed on the surface of the second substrate 112, and shapes thereof can be the same or different to that of the first alignment patterns 116a-116e. Similarly, each of the second alignment patterns 117a-117e has at least one widest part and at least one narrowest part, and after the second substrate 112 is bonded to the first substrate 111, the widest parts or the narrowest parts of the second alignment patterns 117a-117e are aligned or close to the central portions of the contacts 113. The design and arrangement of the second alignment patterns 117a-117e are all similar to that of the first alignment patterns 116a-116e, and therefore detailed descriptions thereof are not repeated.

A method for analysing a bonding quality of the package structure having the alignment pattern is described in detail. First, after the first substrate 111 of FIG. 2A and the second substrate 112 of FIG. 2B are bonded, the polishing process is started from a side surface 211 of the two substrates 111 and 112.

When the polishing process is just started, the widest parts or the narrowest parts of the alignment patterns 116a-116e are still not exposed, and now a fast polishing process can be performed. Then, when the widest part or the narrowest part of the alignment pattern 116a is about to be exposed, it represents that the first conductive structure 114 and the contact 113 are approached. Therefore, the polishing process can be slowed down to a slow polishing process.

As the slow polishing process continues, shapes of the alignment patterns on the substrate are varied. Next, referring to FIGS. 2A, 2B and 1A, in the embodiment, when the narrowest parts of the first and the second alignment patterns 116a and 117a and the widest parts of the first alignment patterns 116b, 116c and 116e and the second alignment patterns 117b, 117c and 117e are exposed, i.e. the position of a dot line a-a′ is exposed, it represents that the substrate polishing approaches the central portions of the first row of the contacts 113. Since arrangements of the first alignment pattern 116e and the second alignment pattern 117e are two-dimensional, by observing the arrangements of the first alignment pattern 116e and the second alignment pattern 117e, a code, “10001” can be obtained by reading the alignment patterns from the left to the right, wherein “1” represents there has the alignment pattern, and “0” represents that there has no alignment pattern. In other words, two-dimensional coding can be performed to the contact positions based on the two-dimensional arranged alignment patterns for identification.

Next, the polishing process is continued. Referring to FIGS. 2A, 2B and 1B, when the polishing process approaches a dot line b-b′ on the first substrate 111 and the second substrate 112, the narrowest parts of the first and the second alignment patterns 116a and 117a and the widest parts of the first alignment patterns 116b, 116c and 116e and the second alignment patterns 117b, 117c and 117e are exposed, which represents that the substrate polishing approaches the central portions of the contacts 113. Similarly, by observing the arrangements of the first alignment pattern 116e and the second alignment pattern 117e, a code “11101” can be obtained by reading the alignment patterns from the left to the right.

It should be noted that when the polishing process continues, if the exposed parts of the first alignment patterns 116a-116e and the second alignment patterns 117a-117e are not the widest parts or the narrowest parts, it represent that the substrate polishing still not approaches the central portions of the contacts 113, which is shown as a position c-c′ on the first substrate 111 and the second substrate 112 in FIGS. 2A, 2B and 1C. Referring to FIGS. 2A, 2B and 1C, when the substrate polishing approaches the position c-c′ on the first substrate 111 and the second substrate 112, it is obvious that this position is not the central portion of the contact 113 according to the cross-sectional view of the package structure 110.

In the following content, the method of analysing the bonding quality of the package structure via polishing is further described in form of a flowchart.

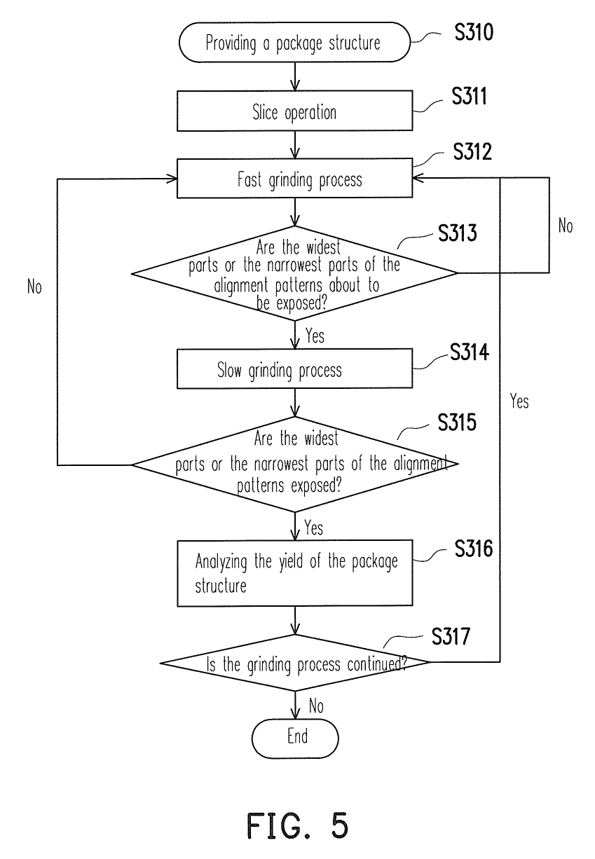

FIG. 5 is a flowchart illustrating a method for analysing a bonding quality of a package structure according to an embodiment. First, in step S310, a package structure is provided, which is as that described in the embodiment of FIGS. 2A, 2B and 1A. In an embodiment, before the polishing process is performed, a slice operation is first performed (step S311). Next, the polishing process is started from the side surface of the package structure, and before the widest parts or the narrowest parts of the alignment patterns are exposed, the fast polishing process can be first performed (step S312). Next, whether the widest parts or the narrowest parts of the alignment patterns are about to be exposed is determined (step S313). If yes, the polishing process is slowed down to perform a slow polishing process (step S314).

Next, in step S315, when the widest parts or the narrowest parts of the alignment patterns are exposed, or when a position close to the widest parts or the narrowest parts of the alignment patterns is exposed, the polishing process is stopped. Now, the polishing process approaches the central portions of the contacts. Therefore, a detection and analysis device can be used to analyse the bonding quality of the package structure of the contacts (step S316), wherein the detection and analysis device includes an optical microscope (OM) or a scanning electron microscope (SEM). Finally, after an analysis result is obtained, the polishing process can be continued or stopped (step S317). In detail, after the bonding quality of the contacts is analysed in step S316, it represents that analysing of such row or column of the contacts is completed. Next, the polishing can be continued according to actual requirements for performing analysis to the contacts of a next row or a next column. If the polishing is selected to be continued in the step S317, the step S312 is then repeated, and if the polishing is selected to be stopped in the step S317, the flowchart is then ended.

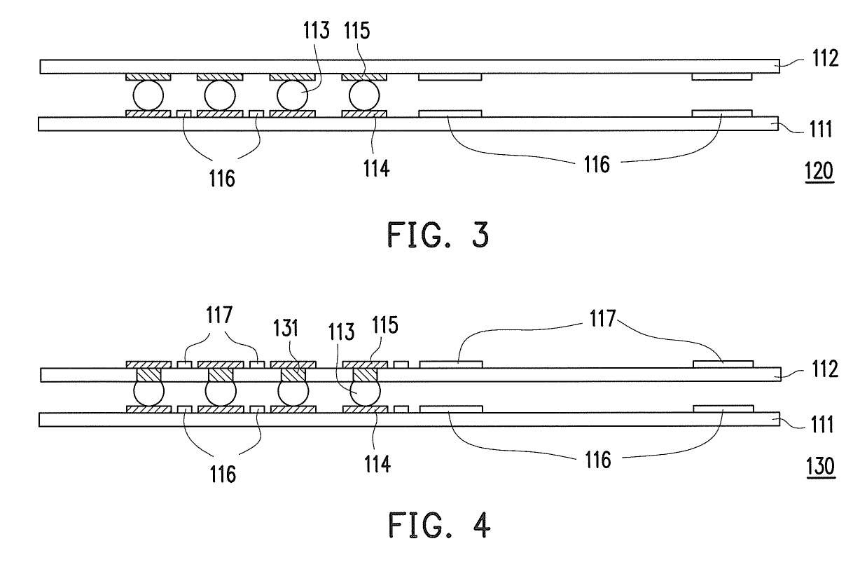

The aforementioned package structure and the method for analysing the bonding quality of the package structure are all based on the package structure that the alignment patterns are designed on both two substrates, though the present invention is not limited thereto. In other embodiments, the alignment patterns can be disposed on only one of the substrate of the package structure, as that shown in FIG. 3. In the package structure of FIG. 3, the alignment pattern 116 is only disposed on the first substrate 111, and none alignment pattern is disposed on the second substrate 112.

Moreover, in the aforementioned embodiment, the package structure includes two face-to-face bonded substrates, though the embodiment is not limited thereto. In other embodiment, the package structure can also include a plurality of stacked substrates shown in FIG. 4. In the embodiment of FIG. 4, the second conductive structure 115 of the second substrate 112 is not disposed face to the first substrate 111, but is disposed back to the first substrate 111, and a plurality of contact structures 131 is formed in the second substrate 112, wherein the contact structures 131 are electrically connected to the conductive structure 115. Therefore, when the second substrate 112 is stacked on the first substrate 111, the contact structures 131 on the second substrate 112 are bonded to the contacts 113 on the first substrate 111. Devices on the first substrate 111 can be electrically connected to devices on the second substrate 112 via the contacts 113 and the contact structures 131.

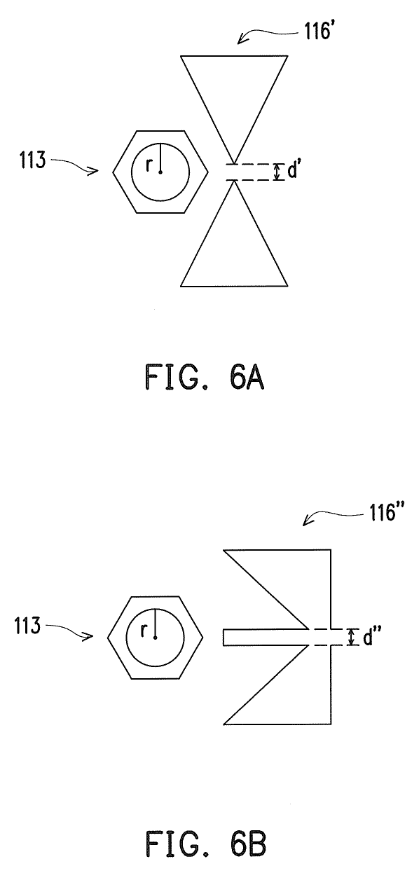

It should be noted that in the embodiment, the widest part or the narrowest part of each of the first alignment patterns 116a-116e is aligned to the central portion of each of the contacts 113, as shown in FIG. 2A, though the embodiment is not limited thereto. FIG. 6A and FIG. 6B are amplified diagrams of a part of alignment patterns and a contact according to another embodiment. Referring to FIG. 6A and FIG. 6B, in the embodiment, the narrowest parts of the alignment patterns 116′ and 116″ are close to the central portion of the contact 113, and spaces d′ and d″ are respectively between the narrowest parts of the alignment pattern 116′ and the narrowest parts of the alignment pattern 116″, wherein the spaces d′ and d″ are all less than a half of a radius r of the ball contact 113. When the substrate polishing is performed for analysing the contacts 113, if the narrowest parts of the alignment patterns are exposed, it represents that the polishing process approaches the central portions of the contacts 113. Therefore, even if an extreme end of the alignment pattern 116′ is not aligned to the central portion of the contact 113, or a shape of the alignment pattern 116′ is irregular, the method for analysing the bonding quality of the package structure can still be applied without decreasing of accuracy.

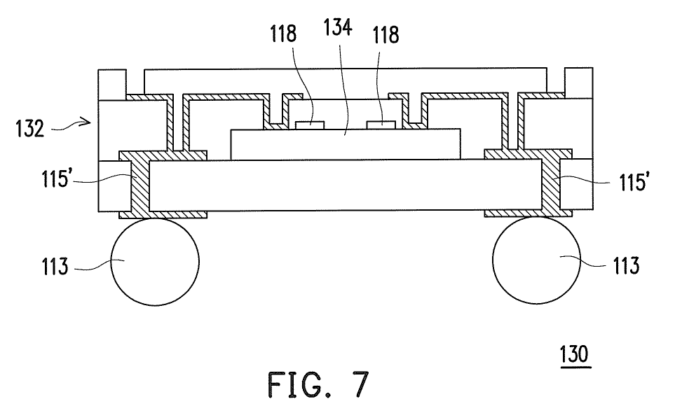

FIG. 7 is a cross-sectional view of a package structure with an alignment pattern according to another embodiment. Referring to FIG. 7, a difference between the embodiment and the aforementioned embodiment is that the package structure of FIG. 7 is an embedded chip package structure. In the package structure 130, at least one chip 134 is embedded in the substrate 132, and a surface of the chip 134 has at least one alignment pattern 118.

The package structure 130 of the embodiment includes a substrate 132 having a multi-layer structure and the chip 134 embedded in the substrate 132. The substrate 132 has at least one conductive structure 115′. The chip 134 is embedded in the substrate 132 and is electrically connected to the conductive structure 115′ in the substrate 132, and the surface of the chip 134 has at least one alignment pattern 118. Moreover, the contacts 113 are located at an outer surface of the substrate 132, wherein the alignment pattern 118 has at least one widest part and at least one narrowest part, and the widest part or the narrowest part is aligned or close to the central portion of the contact 113. A shape and an arrangement of the alignment pattern 118 on the surface of the chip 134 are the same or similar to that of the alignment patterns described in the aforementioned embodiments. The alignment pattern 118 can be any of the alignment patterns 116a-116e shown in FIG. 2A or combinations thereof, or can be the alignment pattern 116′ or 116″ shown in FIG. 6A or FIG. 6B.

Similar to the package structure of the aforementioned embodiment, when the substrate polishing is performed for analysing the contacts, as polished positions of the substrate are varied, exposed positions of the alignment patterns on the chip are also varied. Therefore, by determining the positions of the widest parts or the narrowest parts of the alignment patterns on the chip, whether the central portion of the contact is approached can be determined, so that the alignment patterns can serve as reference patterns for the substrate polishing.

In summary, the embodiment provides a package structure with the alignment patterns and a method for analysing the bonding quality of the package structure. During analysing the bonding quality of the package structure, as the polishing process continues, the positions of the substrate can be identified by observing variations of the alignment patterns on the substrate or the chip, so as to avoid excessive substrate polishing.

It will be apparent to those skilled in the art that various modifications and variations can be made to the structure of the embodiment without departing from the scope or spirit of embodiment. In view of the foregoing, it is intended that the embodiment cover modifications and variations of this embodiment provided they fall within the scope of the following claims and their equivalents.

What is claimed is:

1. A package structure having an alignment pattern, comprising:
a first substrate, having at least one first conductive structure and at least one first alignment pattern thereon;
a second substrate, disposed opposite to the first substrate and having at least one second conductive structure thereon; and
at least one contact, located between the at least one first conductive structure of the first substrate and the at least one second conductive structure of the second structure,
wherein the at least one first alignment pattern has at least one widest part and at least one narrowest part, and the widest part or the narrowest part is aligned or close to a central portion of the at least one contact.

2. The package structure having an alignment pattern as claimed in claim 1, wherein the at least one first alignment pattern comprises a plurality of first alignment patterns, and the at least one contact comprises a plurality of contacts, and the widest part or the narrowest part of each of the first alignment patterns is aligned or close to the central portion of each of the contacts.

3. The package structure having an alignment pattern as claimed in claim 2, wherein the first alignment patterns are disposed as one-dimensional arrangement or two-dimensional arrangement.

4. The package structure having an alignment pattern as claimed in claim 2, wherein the first alignment patterns are consecutively or inconsecutively arranged.

5. The package structure having an alignment pattern as claimed in claim 2, wherein the first alignment patterns are located at an edge of the first substrate or located among the contacts.

6. The package structure having an alignment pattern as claimed in claim 2, wherein sizes of the first alignment patterns are not all the same.

7. The package structure having an alignment pattern as claimed in claim 1, wherein the widest part of the at least one first alignment pattern is located at a central portion thereof, and the narrowest part of the at least one first alignment pattern is located at two sides thereof.

8. The package structure having an alignment pattern as claimed in claim 1, wherein a shape of the at least one first alignment pattern is a diamond, a round, an oval, a parallelogram, a square, a triangle or a polygon.

9. The package structure having an alignment pattern as claimed in claim 1, further comprising at least one second alignment pattern located on a surface of the second substrate, wherein the at least one second alignment pattern has at least one widest part and at least one narrowest part, and the widest part or the narrowest part of the at least one second alignment pattern is aligned or close to the central portion of the at least one contact.

10. The package structure having an alignment pattern as claimed in claim 1, wherein the at least one first conductive structure is located at an inner surface of the first substrate, and the at least one second conductive structure is located at an inner surface of the second substrate.

11. The package structure having an alignment pattern as claimed in claim 1, wherein the at least one first conductive structure is located at the inner surface of the first substrate, and the at least one second conductive structure is located at an outer surface of the second substrate.

12. The package structure having an alignment pattern as claimed in claim 1, wherein the first substrate and the second substrate are respectively a chip, a glass substrate, a ceramic substrate, a plastic substrate or a metal substrate.

13. A substrate structure having an alignment pattern, comprising:
a substrate, having at least one first conductive structure and at least one first alignment pattern; and
at least one contact, located on the conductive structure of the substrate,
wherein the at least one first alignment pattern has at least one widest part and at least one narrowest part, and the widest part or the narrowest part is aligned or close to a central portion of the at least one contact.

14. The substrate structure having an alignment pattern as claimed in claim 13, wherein the at least one first alignment pattern comprises a plurality of first alignment patterns, and the at least one contact comprises a plurality of contacts, and the widest part or the narrowest part of each of the first alignment patterns is aligned or close to the central portion of each of the contacts.

15. The substrate structure having an alignment pattern as claimed in claim 14, wherein the first alignment patterns are disposed as one-dimensional arrangement or two-dimensional arrangement.

16. The substrate structure having an alignment pattern as claimed in claim 14, wherein the first alignment patterns are consecutively or inconsecutively arranged.

17. The substrate structure having an alignment pattern as claimed in claim 14, wherein the first alignment patterns are located at an edge of the substrate or located among the contacts.

18. The substrate structure having an alignment pattern as claimed in claim 14, wherein sizes of the first alignment patterns are not all the same.

19. The substrate structure having an alignment pattern as claimed in claim 13, wherein the widest part of the at least one first alignment pattern is located at a central portion thereof, and the narrowest part of the at least one first alignment pattern is located at two sides thereof.

20. The substrate structure having an alignment pattern as claimed in claim 13, wherein a shape of the at least one first alignment pattern is a diamond, a round, an oval, a parallelogram, a square, a triangle or a polygon.

21. The substrate structure having an alignment pattern as claimed in claim 13, wherein the substrate is a chip, a glass substrate, a ceramic substrate, a plastic substrate or a metal substrate.

22. A package structure having an alignment pattern, comprising:
a substrate, having at least one conductive structure;
at least one chip, embedded in the substrate, wherein the chip is electrically connected to the conductive structure in the substrate, and a surface of the chip has at least one alignment pattern; and
at least one contact, located on an outer surface of the substrate,
wherein the at least one alignment pattern has at least one widest part and at least one narrowest part, and the widest part or the narrowest part is aligned or close to a central portion of the at least one contact.

23. The package structure having an alignment pattern as claimed in claim 22, wherein the at least one alignment pattern comprises a plurality of alignment patterns, and the at least one contact comprises a plurality of contacts, and the widest part or the narrowest part of each of the alignment patterns is aligned or close to the central portion of each of the contacts.

24. The package structure having an alignment pattern as claimed in claim 23, wherein the alignment patterns are disposed as one-dimensional arrangement or two-dimensional arrangement.

25. The package structure having an alignment pattern as claimed in claim 23, wherein the alignment patterns are consecutively or inconsecutively arranged.

26. The package structure having an alignment pattern as claimed in claim 23, wherein sizes of the alignment patterns are not all the same.

27. The package structure having an alignment pattern as claimed in claim 22, wherein the widest part of the at least one alignment pattern is located at a central portion thereof, and the narrowest part of the at least one alignment pattern is located at two sides thereof.

28. The package structure having an alignment pattern as claimed in claim 22, wherein a shape of the at least one alignment pattern is a diamond, a round, an oval, a parallelogram, a square, a triangle or a polygon.
